(19) United States
(12) Patent Application Publication
(10) Pub. No.: US 2025/0287686 A1
(43) Pub. Date: Sep. 11, 2025

(54) CO-INTEGRATION OF DIFFERENT GATE DIELECTRIC THICKNESSES WITH NANOSHEET TECHNOLOGY

(71) Applicant: INTERNATIONAL BUSINESS MACHINES CORPORATION, Armonk, NY (US)

(72) Inventors: Gen Tsutsui, Glenmont, NY (US); Ruqiang Bao, Niskayuna, NY (US); Anthony I. Chou, Guilderland, NY (US); Shahab Siddiqui, Clifton Park, NY (US)

(21) Appl. No.: 18/597,491

(22) Filed: Mar. 6, 2024

(51) Int. Cl. H01L 27/088; H01L 21/8234

(52) U.S. Cl. CPC H10D 84/834; H10D 84/0128; H10D 84/0142; H10D 84/0144; H10D 84/0158; H10D 84/038

(57) ABSTRACT

A semiconductor device includes an input/output device having a constructed fin channel extending orthogonally relative to a plane of a substrate. The fin channel includes faceted portions. A first gate dielectric layer is disposed on the faceted portions. A logic device has a nanosheet channel. A second gate dielectric layer is disposed on the first gate dielectric layer on the nanosheet channel.

### BACKGROUND

The present invention generally relates to semiconductor devices and processing methods, and more particularly to input/output nanosheet transistors and logic transistors co-integrated on a same wafer having gate dielectrics with different thicknesses.

Input/output (I/O) devices, which can also be referred to as extra gate (EG) devices, need a thicker gate dielectric than other transistor devices on a chip to meet reliability requirements. Other devices, such as logic devices may only need a single gate (SG) thickness. Integration of these types of devices on a same wafer can lead to challenges in processing. Such challenges can include the need for separate integration steps for each device to ensure appropriate gate dielectric thicknesses for the different devices on the same wafer.

These challenges become more pronounced when employing nanosheet technology. Due to limited space between nanosheet layers, dielectric thickness is limited. This limitation can affect device performance even when using high dielectric constant (high-k) materials.

Therefore, a need exists for integration of thick gate dielectric devices with thin gate dielectric devices in concurrently performed fabrication methods and device structures that result from such integration.

### SUMMARY

In accordance with an embodiment of the present invention, a semiconductor device includes an input/output device having a constructed fin channel extending orthogonally relative to a plane of a substrate. The fin channel includes faceted portions. A first gate dielectric layer is disposed on the faceted portions. A logic device has a nanosheet channel. A second gate dielectric layer is disposed on the first gate dielectric layer on the nanosheet channel.

In other embodiments, the faceted portions can include periodic faceted surfaces having a periodicity in accordance with nanosheets. The faceted portions can include a diamond-like shape. The constructed fin channel can include inner spacers embedded therein. The first gate dielectric layer can include a thickness greater than a gap between nanosheets in the nanosheet channel. The thickness can be greater than 3 nm. The constructed fin channel can include nanosheets joined by epitaxial semiconductor material.

In accordance with another embodiment of the present invention, a semiconductor device includes an input/output device having a constructed fin channel extending orthogonally relative to a plane of a substrate, the fin channel including faceted portions with peaks and valleys on an outer surface of the fin channel. A first gate dielectric layer is disposed on the faceted portions over the peaks and valleys of the outer surface. A logic device has a nanosheet channel, and a second gate dielectric layer is disposed on the first gate dielectric layer on the nanosheet channel.

In other embodiments, the faceted portions can include periodic faceted surfaces having a periodicity in accordance with nanosheets. The faceted portions can include a diamond-like shape. The constructed fin channel can include inner spacers embedded therein. The first gate dielectric layer can include a thickness greater than a gap between nanosheets in the nanosheet channel. The thickness can be greater than 3 nm. The constructed fin channel can include nanosheets joined by epitaxial semiconductor material.

In accordance with another embodiment of the present invention, a semiconductor device includes an input/output device having a constructed fin channel extending orthogonally relative to a plane of a substrate, the fin channel including faceted portions with peaks and valleys on an outer surface of the fin channel. A first gate dielectric layer is disposed on the faceted portions, and a second gate dielectric layer is disposed on the first gate dielectric layer. A first gate electrode is on the second gate dielectric layer, the first gate electrode having a profile that conforms with the peaks and valleys of the outer surface of the fin channel. A logic device has a nanosheet channel.

In other embodiments, the faceted portions can include periodic faceted surfaces having a periodicity in accordance with nanosheets. The faceted portions can include a diamond-like shape. The constructed fin channel can include inner spacers embedded therein. The first gate dielectric layer can include a thickness greater than a gap between nanosheets in the nanosheet channel. The thickness can be greater than 3 nm. The constructed fin channel can include nanosheets joined by epitaxial semiconductor material.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views X1, X2, Y1 and Y2, taken at section lines X1, X2, Y1 and Y2, in top-down layout views of a semiconductor wafer having dummy gates and a nanosheet stack for two types of devices, e.g., logic devices and input/output (I/O) devices that can be formed on a same substrate, in accordance with an embodiment of the present invention;

FIG. 2 shows cross-sectional views X1, X2, Y1 and Y2 having dummy gate material removed from the two types of devices, in accordance with an embodiment of the present invention;

FIG. 3 shows cross-sectional views X1, X2, Y1 and Y2 having a blocking mask formed over one type of device to process the other type of device, in accordance with an embodiment of the present invention;

FIG. 4 shows cross-sectional views X1, X2, Y1 and Y2 with the device being processed etched to remove selected alternating layers from the nanosheet stack, in accordance with an embodiment of the present invention;

FIG. 5 shows cross-sectional views X1, X2, Y1 and Y2 with the device being processed having epitaxial semiconductor material deposited to join the nanosheets and construct a continuous constructed fin that include faceted portions that contribute to extended surface area for a gate conductor, in accordance with an embodiment of the present invention;

FIG. 6 shows cross-sectional views X1, X2, Y1 and Y2 with a blocking mask removed and a first gate dielectric being conformally formed over the wafer, in accordance with an embodiment of the present invention;

FIG. 7 shows cross-sectional views X1, X2, Y1 and Y2 with another blocking mask formed to cover the processed device, in accordance with an embodiment of the present invention;

FIG. 8 shows cross-sectional views X1, X2, Y1 and Y2 with the unmasked device being opened up to expose the nanosheets, in accordance with an embodiment of the present invention;

FIG. 9 shows cross-sectional views X1, X2, Y1 and Y2 with the unmasked device being etched to remove selected alternating layers from the nanosheet stack, in accordance with an embodiment of the present invention;

FIG. 10 shows cross-sectional views X1, X2, Y1 and Y2 with the blocking mask removed, in accordance with an embodiment of the present invention;

FIG. 11 shows cross-sectional views X1, X2, Y1 and Y2 with a second gate dielectric conformally formed over the wafer for both types of devices, in accordance with an embodiment of the present invention;

FIG. 12 shows cross-sectional views X1, X2, Y1 and Y2 with a gate conductor conformally formed over both types of devices, in accordance with an embodiment of the present invention; and

FIG. 13 shows cross-sectional views X1, X2, Y1 and Y2 with the gate conductor planarized to form gate electrodes for both types of devices, in accordance with an embodiment of the present invention.

### DETAILED DESCRIPTION

In accordance with embodiments of the present invention, devices and methods are described which include co-integrating transistor devices having different gate dielectric characteristics. In an embodiment, the gate dielectrics of two types of devices have different thicknesses. Embodiments in accordance with the present invention provide gate dielectric material on nanosheet channels for logic devices and provide a new structure for extended gate (EG) devices. The new structure includes a fin-like structure constructed from nanosheets and grown semiconductor material. The logic devices include nanosheet field effect transistors (FET) with single gate (SG) logic. The EG devices, which can include input/output (I/O) devices or FETs are co-integrated on a same wafer as the logic devices without adding a complex integration flow. The I/O device includes a channel having a faceted shape, e.g., a diamond shape.

The logic devices can include a gate dielectric that surrounds multiple nanosheets to form channels in the nanosheet layers of the logic device. The I/O device includes a constructed fin that can have a faceted shape for its channel structure. The constructed fin channel can include nanosheets joined by epitaxial semiconductor material. In some embodiments, faceted portions of the faceted shape can include periodic faceted surfaces having a periodicity in accordance with nanosheets. Since material of the nanosheets is employed to initiate crystal growth, the faceted portions can include a diamond-like shape with the periodicity of the nanosheets. The constructed fin channel having the faceted portion can include inner spacers embedded therein. The inner spacers are embedded within a portion of the constructed fin structure and can be employed to obstruct current leakage paths.

The I/O device includes a thicker gate dielectric than the logic device. In an embodiment, the thicker gate dielectric of the I/O device is formed using multiple dielectric layers. In one example, the gate dielectric can include, e.g., SiO₂ or SiON followed by HfO₂. The thicker gate dielectric can include a thickness greater than a gap between nanosheets in the nanosheet channel. The thickness can be greater than 3 nm.

A method for forming the device channel structure for the I/O device can include removing alternating layers from a nanosheet. Epitaxially growing additional semiconductor material on remaining nanosheets to form a fin-like structure. The additional semiconductor material fills in gaps between the nanosheets and grows beyond the nanosheets to form a faceted structure. A thick gate dielectric is formed over the fin-like faceted structure of the I/O devices. The thickness of the gate dielectric can exceed, e.g., 3 nm, and is not limited to less than 3 nm as is the case for conventional devices due to nanosheet spacing limitations. The diamond faceted shape of the I/O devices can include enhanced channel dimensions and can include a thicker gate dielectric than permitted between nanosheets. In an embodiment, the gate dielectric of the I/O devices can include a first layer of, e.g., SiO₂ or SiON followed by a layer of a high dielectric constant materials, such as, e.g., HfO₂.

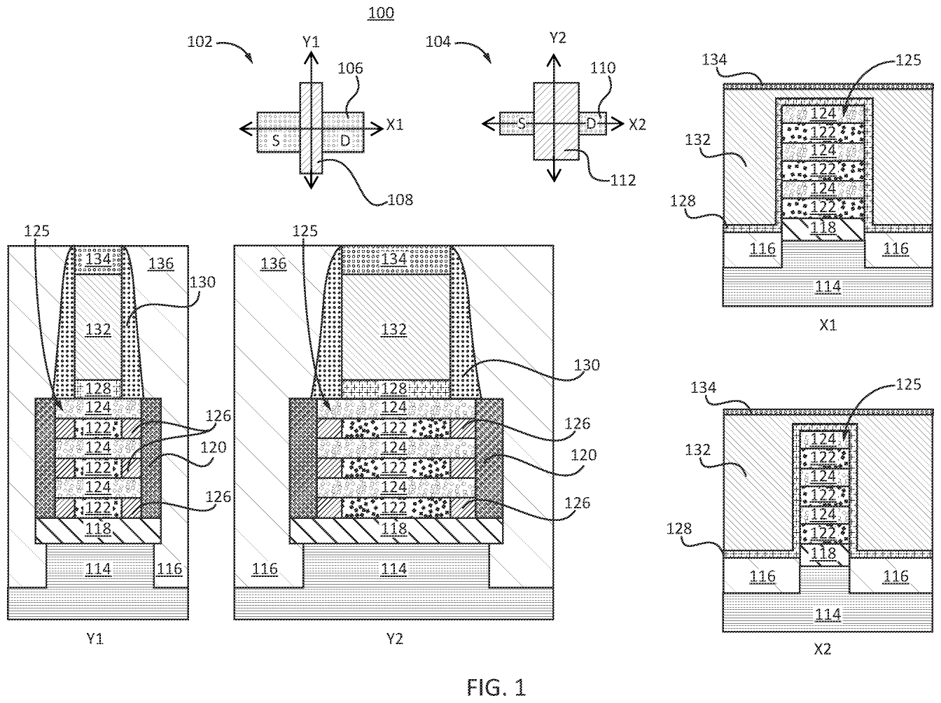

Referring now to the drawings in which like numerals represent the same or similar elements and initially to FIG. 1, devices and methods for manufacturing nanosheet field effect transistors (FETs) are shown in accordance with embodiments of the present invention. A wafer 100 includes a substrate 114, which can include one or more layers on which FET devices will be fabricated. FIG. 1 depicts two layout views 102 and 104 of different regions of the wafer 100. Layout view 102 shows a top down view of a logic region of the wafer 100 having source/drain regions 106 and a gate region 108. Section lines X1 and Y1 correspond to sections X1 and Y1 for the logic region. Layout view 104 shows a top down view of an input/output (I/O) region (e.g., extended gate (EG) devices) of the wafer 100 having source/drain regions 110 and a gate region 112. Section lines X2 and Y2 correspond to sections X2 and Y2 for the I/O region. Corresponding X1, X2, Y1 and Y2 views are depicted throughout the FIGS. Views Y1 and X1 correspond with logic devices, while views Y2 and X2 correspond to I/O devices. Source/drain regions 106 and 110 represent source/drain regions for transistor devices to be formed, and gate regions 108 and 112 are represented for such transistor devices. Transistor channels are formed at intersections of lines for source/drain regions 106 and 110 and the gate regions 108 and 112.

The substrate 114 can include any suitable substrate structure, e.g., a bulk semiconductor, a semiconductor-on-insulator (SOI) substrate, etc., and preferably includes a monocrystalline semiconductor. In one example, the substrate 114 can include a silicon-containing material. Illustrative examples of Si-containing materials suitable for the substrate 114 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

In illustrative examples described here, a nanosheet stack 125 includes a stack of alternating semiconductor materials. In an embodiment, the nanosheet stack 125 includes nanosheets (NS) that can include semiconductor layers 122 and semiconductor layers 124 in an alternate stacking arrangement. A dielectric interface 118 can be formed to provide dielectric isolation between the substrate 114 and components of a nanosheet stack 125.

Each of semiconductor layers 122, 124 are selectively removeable relative to the other adjacent semiconductor layers 124, 122, e.g., by a selective etching process. In one embodiment, the semiconductor layers 122 include SiGe, where Ge can be between 30-55 atomic % of the compound; and semiconductor layers 124 can include Si. It should be understood that other materials or atomic percentages can be employed for the semiconductor layers 122 and 124. In other embodiments, different stack orders and numbers may be employed for the semiconductor layers 122 and 124.

The nanosheet stack 125 can be patterned using lithography and etching, e.g., an anisotropic etch, such as reactive ion etching (RIE), to form channel regions for transistor devices under fabrication (e.g., logic and I/O devices).

The substrate 114 can be etched to form shallow trenches therein. Shallow trench isolation (STI) regions or STI 116 are formed in the shallow trenches. STI 116 can be formed by depositing dielectric material, such as, e.g., SiO₂, SSiOₓN_{y}, SiCO or other suitable compounds in the shallow trenches. STI 116 can be deposited using chemical vapor deposition (CVD), although other deposition methods can be employed. The STI can be leveled off by a recess etch.

A buffer 128 can be formed between a dummy gate 132 and a topmost semiconductor layer 124 of the nanosheet stack 125. The buffer can include a dielectric material, such as e.g., SiN, although other dielectric materials can be employed. The dummy gate 132 can include polysilicon, amorphous Si or other selectively removeable material. A spacer deposition process is employed to form spacers 130. Spacers 130 can include a nitride, such as silicon nitride, although other dielectric materials can be employed. A self-aligned cap (SAC) 134 can be formed over material of the dummy gate 132. The SAC 134 can include a nitride, such as silicon nitride, although other dielectric materials can be employed.

Inner spacers 126 can be formed and include a dielectric material. In an embodiment, the inner spacers 126 are formed using exposed portions of the semiconductor layer 122, which can undergo an oxidation process to form a dielectric oxide (SiO₂) at the exposed portions by a thermal oxidation process. The oxidation process converts SiGe to the dielectric oxide and condenses out Ge. In another embodiment, inner spacers 126 can be formed by selective SiGe indentation (etching the sides of the SiGe) followed by inner spacer material fill and etch back. Sidewall spacers 120 can be formed along sides of the nanosheet stack 125. Sidewall spacers 120 can include a silicon oxide. The buffer 128 can also be employed to protect the sidewalls of the nanosheet stack 125.

An interlevel dielectric (ILD) 136 can be formed. The ILD 136 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, a-C: H.

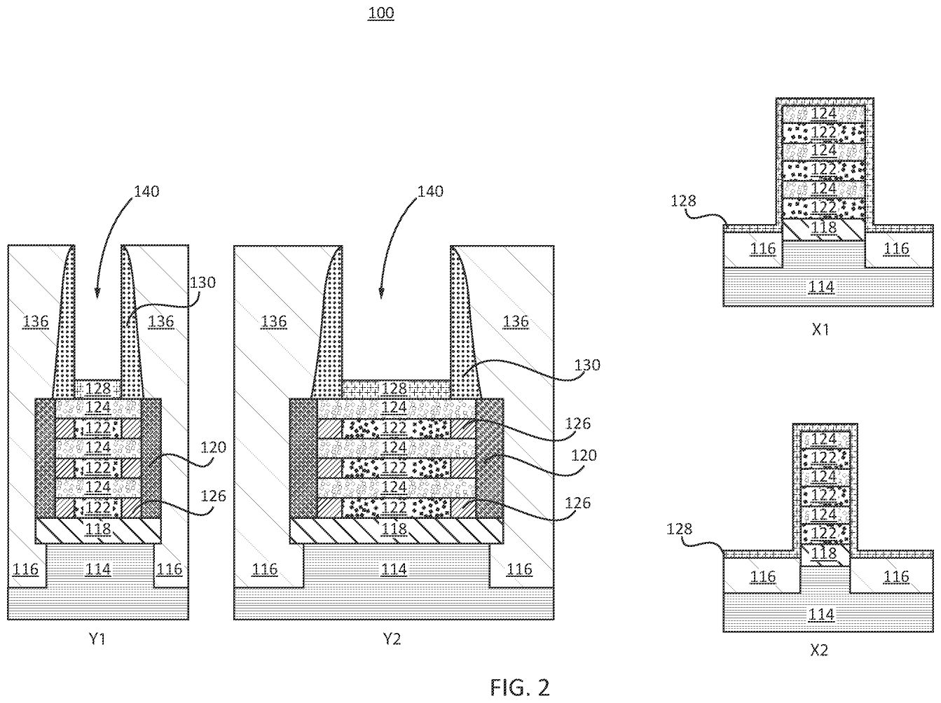

Referring to FIG. 2, the SAC 134 and the material of the dummy gate 132 are removed to provide recesses 140. The recesses 140 expose the buffer 128. The SAC 134 and the material of the dummy gate 132 can be removed by employing an etch process that is selective to the ILD 136, the spacers 130 and the buffer 128.

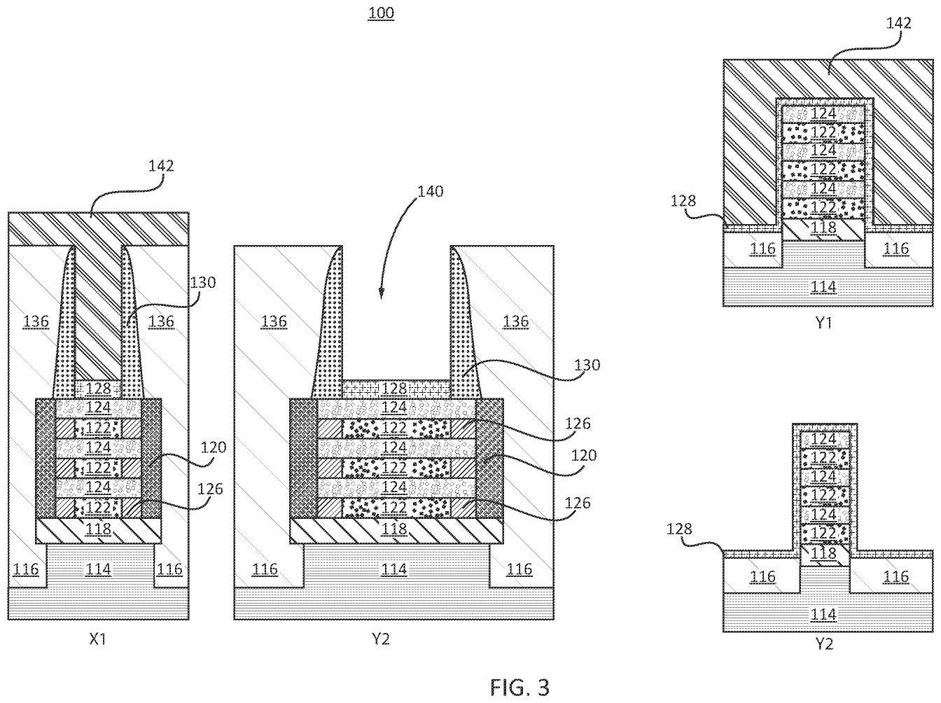

Referring to FIG. 3, a blocking mask 142 is formed over the logic devices (sections Y1 and X1). The blocking mask 142 can be formed by a blanket deposition and removal from the I/O devices (sections Y2 and X2) by a patterned etch. The blocking mask 142 protects logic device regions during further processing of I/O device regions.

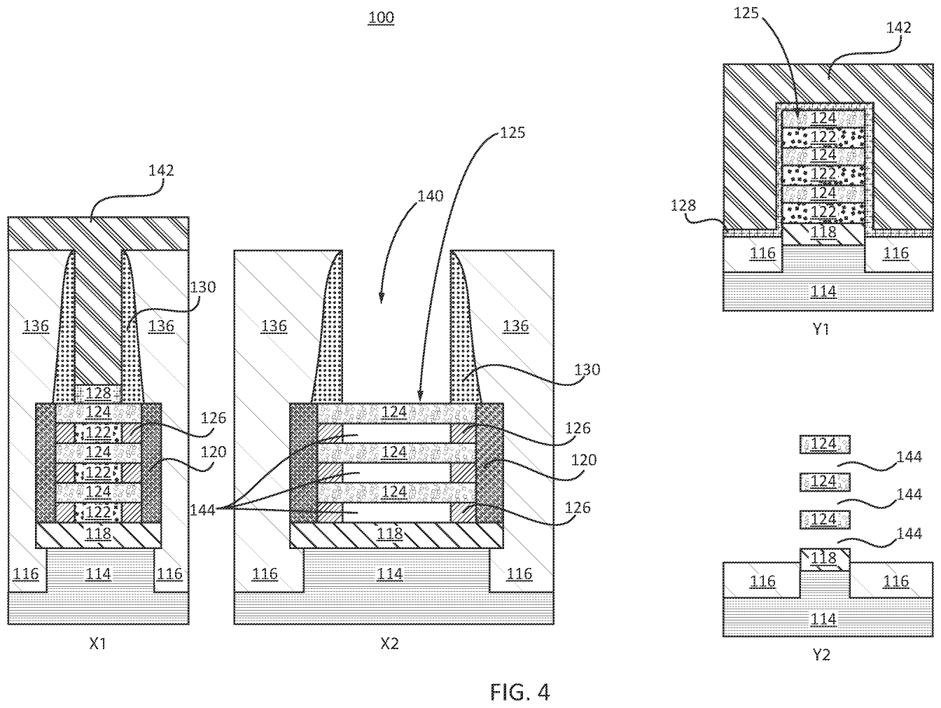

Referring to FIG. 4, the buffer 128 is removed from the recesses 140. The semiconductor layers 122 are removed from the nanosheet stack 125 of the I/O devices. The semiconductor layers 122 can be removed by a wet or dry etch selective to the semiconductor layers 124, the inner spacers 126, the dielectric interface 118 and the spacers 130. This opens up spaces 144 between semiconductor layers 124 and exposes the surface area of the semiconductor layers 124 of the nanosheet stack 125 (for I/O devices).

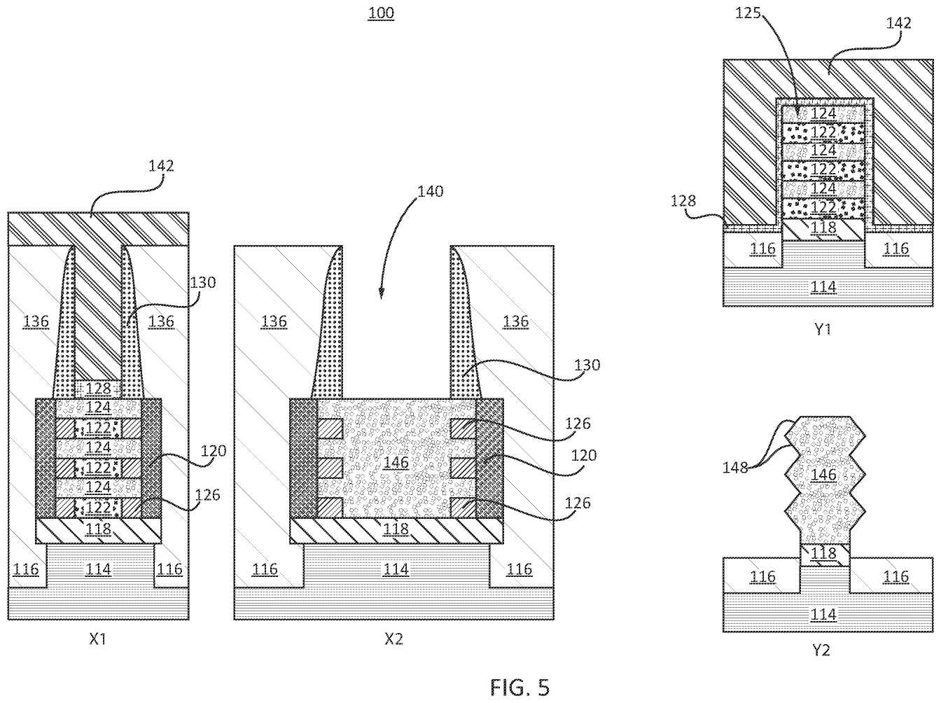

Referring to FIG. 5, exposed semiconductor layers 124 in the I/O device regions are employed as a deposition surface or surfaces for epitaxial growth. Semiconductor material can be grown with substantially the same crystalline characteristics as the semiconductor material of the deposition surface of the semiconductor layers 124. Epitaxy can be performed by ultrahigh vacuum chemical vapor deposition (UHVCVD), rapid thermal chemical vapor deposition (RTCVD), metalorganic chemical vapor deposition (MOCVD), low-pressure chemical vapor deposition (LPCVD), limited reaction processing CVD (LRPCVD), vapor-phase epitaxy (VPE), liquid-phase epitaxy (LPE) and/or molecular beam epitaxy (MBE). Epitaxial materials may be grown from gaseous or liquid precursors.

In an embodiment, epitaxial silicon, silicon germanium (SiGe), and/or carbon doped silicon (Si: C) silicon can be grown and doped during deposition (in-situ doped) by adding dopants, n-type dopants (e.g., phosphorus or arsenic) or p-type dopants (e.g., boron or gallium), depending on the type of transistor. In an embodiment, the semiconductor layers 124 of the nanosheet stack 125 can include Si, and epitaxial silicon is grown to fill in spaces surrounding the semiconductor layers 124.

In addition, the epitaxial growth process provides a constructed fin 146 that is vertically continuous and extends orthogonally relative to a plane of the substrate 114. The plane of the substrate 114 is the plane of the wafer 100. The constructed fin 146 will function as a channel region for an I/O device to be formed. The constructed fin 146 includes vertically continuous semiconductor material (FIG. 5, section X2) and includes textured external surfaces (FIG. 5, section Y2) with faceted portions 148 based on periodicity of the semiconductor layers 124 in unconfined spaces.

The faceted portions 148 can include a repeating pattern (e.g., of diamond shaped protrusions). The pattern repeats in accordance with the periodicity of the nanosheets (e.g., semiconductor layers 124) and spaces 144 (FIG. 4) therebetween. The faceted portions 148 have faceted surfaces that form peaks and valleys, e.g., as a result of crystallographic growth (e.g., diamond shapes) at an outer surface of the constructed fin 146.

The spaces 144 (FIG. 4) would otherwise limit an amount or thickness of a gate dielectric that would encapsulate the semiconductor layers 124, e.g., in a gate all-around structure. Instead, in accordance with embodiments of the present invention, the gate dielectric will be moved to an outer surface of the constructed fin 146 and leverage additional surface area provided by the peaks and valleys in a profile of the constructed fin 146. The constructed fin 146, which forms a fin channel includes inner spacers 126 embedded therein.

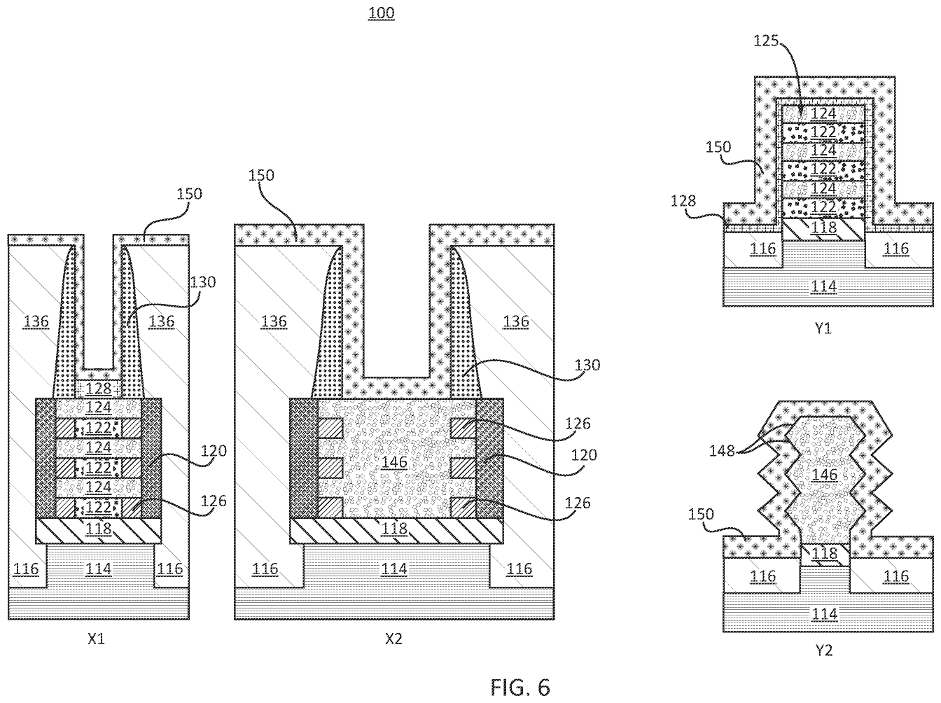

Referring to FIG. 6, the block mask 142 is removed from the wafer 100 to expose the logic devices (sections Y1 and X1). A conformal deposition is performed over surfaces of the wafer 100 to form a first gate dielectric layer 150 over surfaces of the constructed fin 146. The first gate dielectric layer 150 can include silicon oxide, silicon oxynitride, or other suitable conformally deposited dielectric materials. The conformal deposition of first gate dielectric layer 150 can include CVD, plasma enhanced CVD (PECVD), atomic layer deposition (ALD) or other suitable deposition processes. The conformal deposition of first gate dielectric layer 150 follows a profile of the faceted portions 148 of the constructed fin 146.

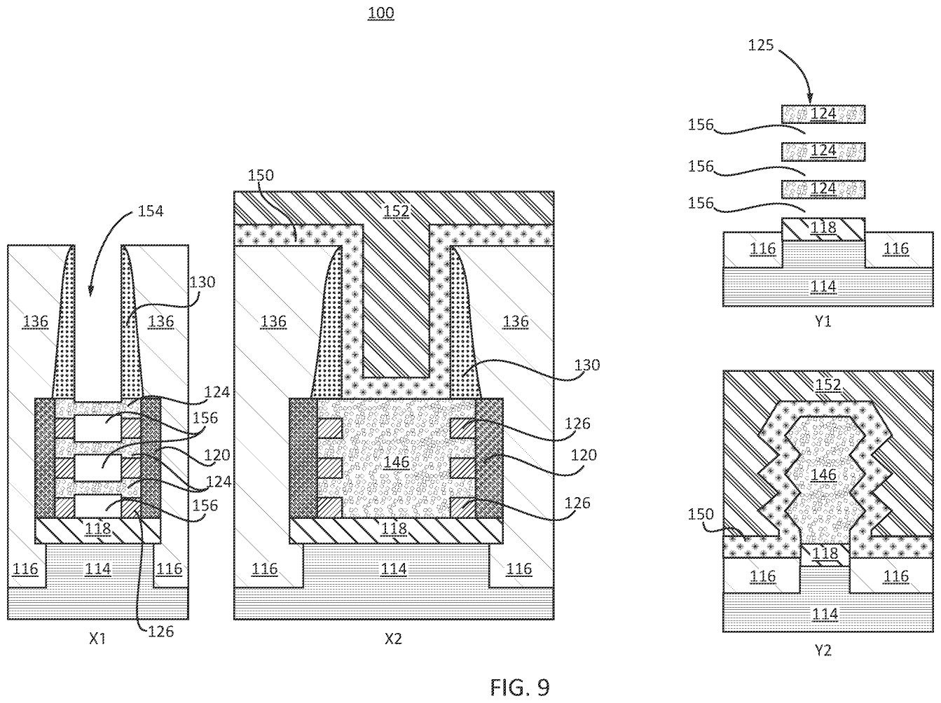

The first gate dielectric layer 150 can be formed to a desired thickness that is not limited by spacings between nanosheet layers (semiconductor layers 124). In an embodiment, a thickness of the first gate dielectric layer 150 can include a thickness greater than a nanosheet gap or spacing (e.g., between semiconductor layers 124 (spaces 144 (FIG. 4) or spaces 156 (FIG. 9))). In an embodiment, the thickness of the first gate dielectric layer 150 can be greater than 3 nm. In some embodiments, the thickness of the first gate dielectric layer 150 can include, e.g., 3-6 nm.

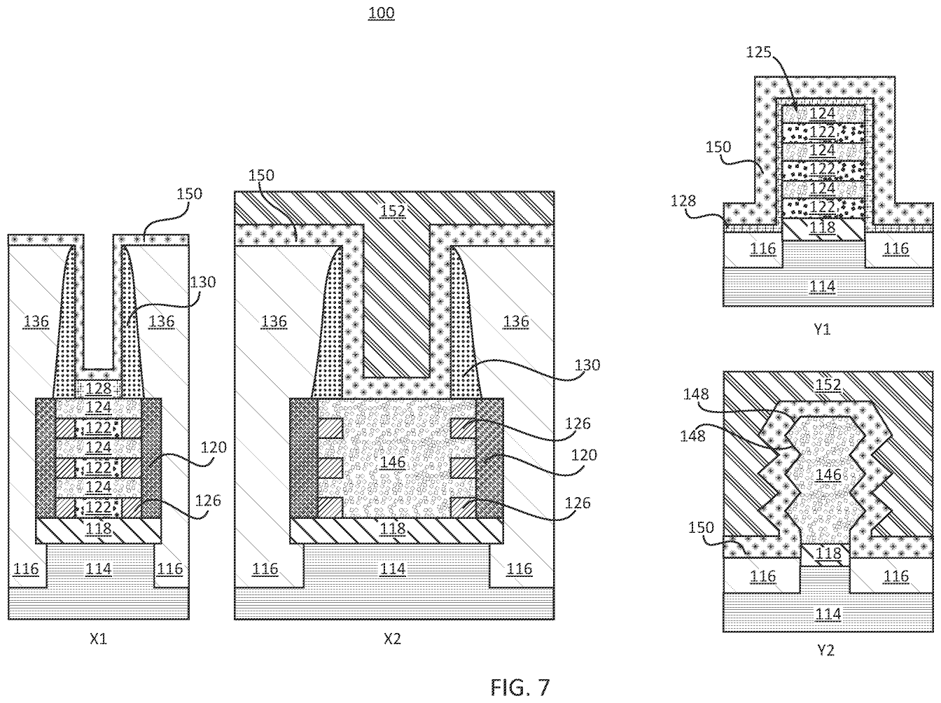

Referring to FIG. 7, a blocking mask 152 is formed over the I/O devices (sections Y2 and X2). The blocking mask 152 can be formed by a blanket deposition and removal from the logic devices (sections Y1 and X1) by a patterned etch. The blocking mask 152 protects I/O device regions during further processing of logic device regions.

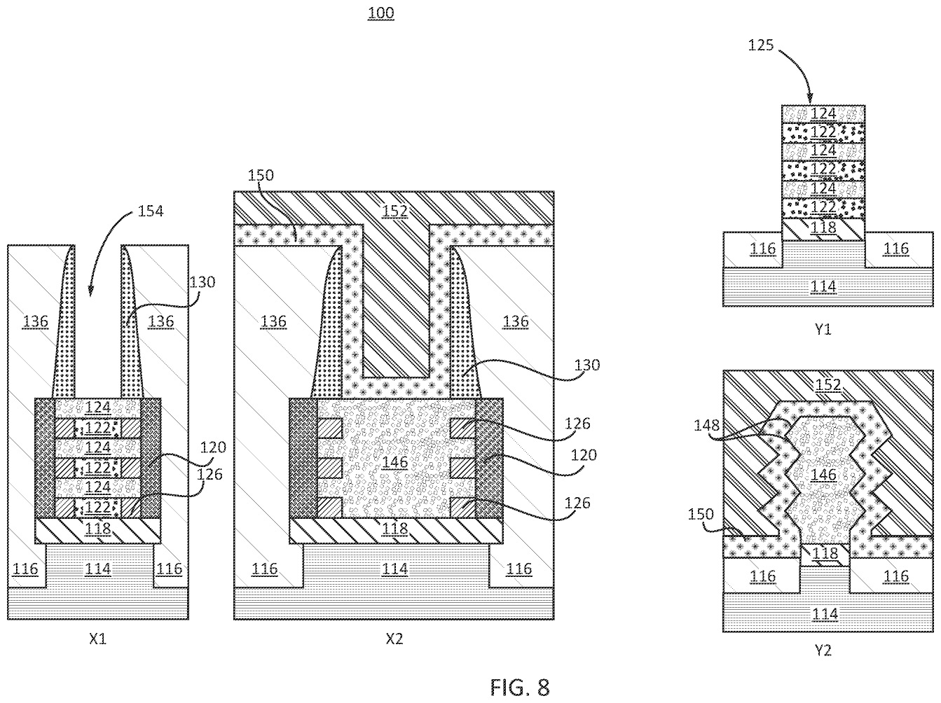

Referring to FIG. 8, the first gate dielectric layer 150 is removed from regions not masked by the blocking mask 152. The buffer 128 is removed from a recess 154 to expose the nanosheet stack 125.

Referring to FIG. 9, the semiconductor layers 122 are removed from the nanosheet stack 125 of the logic devices. The semiconductor layers 122 can be removed by a wet or dry etch selective to the semiconductor layers 124, the inner spacers 126, the dielectric interface 118 and the spacers 130. This opens up spaces 156 between semiconductor layers 124 and exposes the surface area of the semiconductor layers 124 of the nanosheet stack 125 (for logic devices).

The semiconductor layers 124 can undergo some thinning as a result of the etch process. The thinning of the semiconductor layers 124 to the logic devices can be employed as a tuning method to provide a desired channel size for the logic devices to be formed.

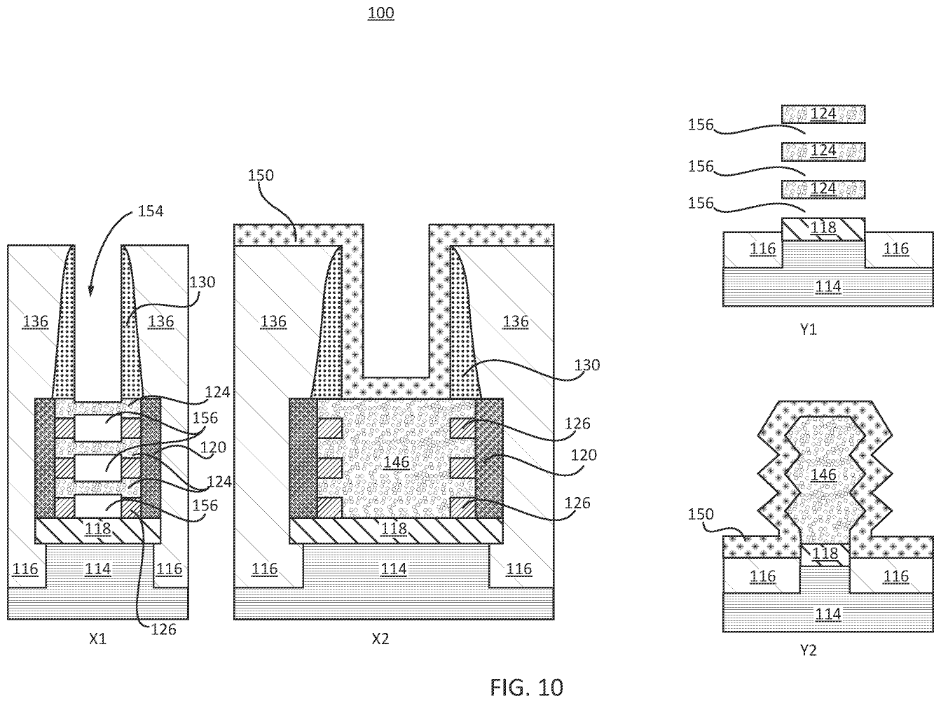

Referring to FIG. 10, the blocking mask 152 is removed. The first gate dielectric layer 150 is exposed in the I/O device regions. The semiconductor layers 124 are exposed in the logic device regions.

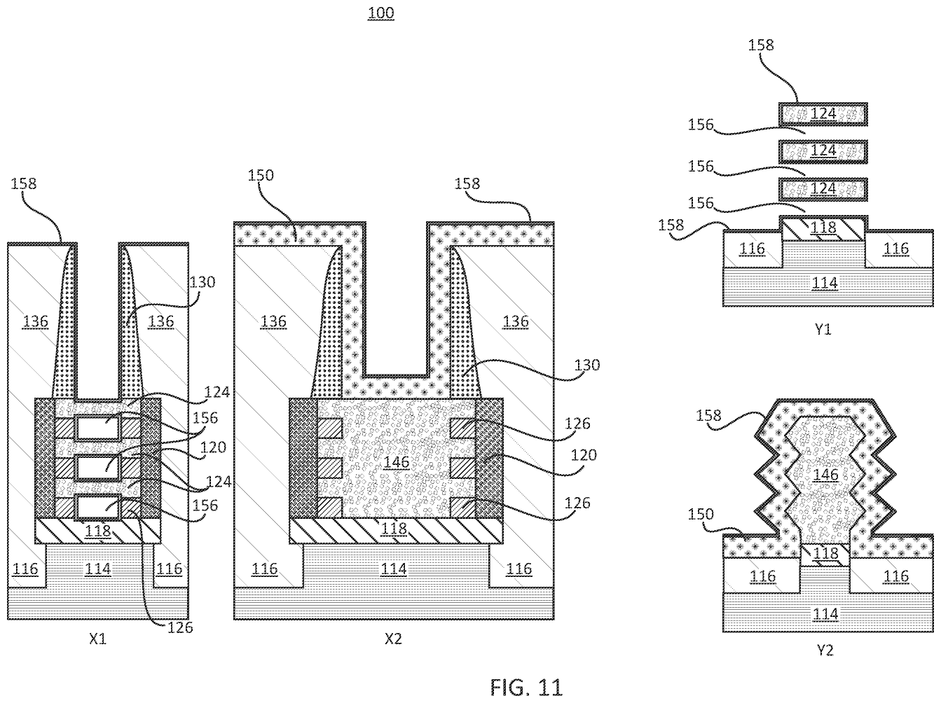

Referring to FIG. 11, a second gate dielectric layer 158 is deposited to cover the exposed semiconductor layers 124 in the logic device regions. The second gate dielectric layer 158 is also deposited to cover the first gate dielectric layer 150 for the I/O device regions.

The second gate dielectric layer 158 can be formed by, e.g., CVD or ALD. Suitable examples of oxides that can be employed for the second gate dielectric layer 158 can include, but are not limited to: Al₂O₃, ZrO₂, HfO₂, Ta₂O₃, TiO₂ and combinations thereof.

In an embodiment, the second gate dielectric layer 158 can include a thinner dielectric and can include a material, such as, e.g., HfO₂. The second gate dielectric layer 158 can have its thickness tuned for proper operation of the logic devices and the I/O devices since this layer is employed for gate dielectrics for both of the types of devices-I/O devices and logic devices. It should be understood that while the logic devices and the I/O devices have been illustratively described for co-integration, co-integration of other devices with different gate dielectric thicknesses are also contemplated. Since two layers, e.g., the first gate dielectric layer 150 and the second gate dielectric layer 158, are stacked, opportunities exist to adjust the overall gate dielectric thickness and resolve any discrepancies in providing the proper thickness of gate dielectric to different types of devices.

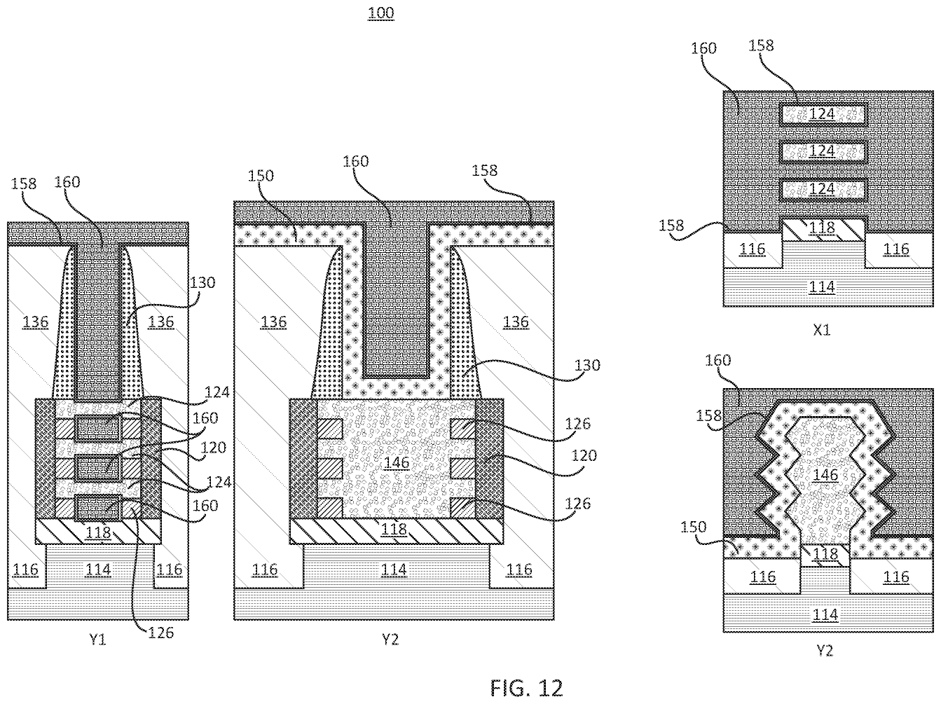

Referring to FIG. 12, a gate conductive material 160 is deposited to cover the second gate dielectric layer 158 and to fill spaces 156 between semiconductor layers 124 in the logic device regions. The gate conductive material 160 can include at least one gate conductor atop the second gate dielectric layer 158. The gate conductive material 160 can include any conductive metal including, but not limited to W, Ni, Ti, Mo, Ta, Cu, Pt, Ag, Au, Ru, Ir, Rh, and Re, and alloys that include at least one of these conductive materials. The gate conductive material 160 can include one or more layers of conductive materials. In one example, a second conductive material may be formed. When a combination of conductive elements is employed, an optional diffusion barrier material such as TaN or WN may be formed between the conductive materials. The gate conductive material 160 can be deposited by CVD, plasma enhanced CVD, ALD or other suitable deposition processes.

The gate conductive material 160 can include a profile that conforms with the peaks and valleys of the outer surface of the constructed fin 146 of the I/O devices on the second gate dielectric layer 158.

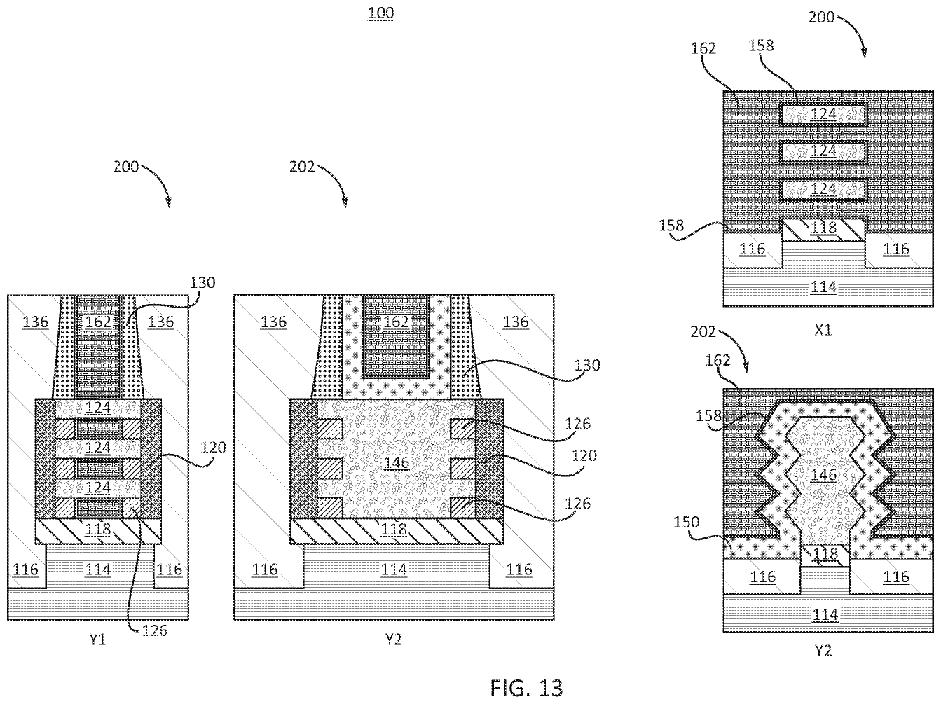

Referring to FIG. 13, after formation of the gate conductive material 160, a planarization process can be performed to planarize a top surface of the wafer 100. In an embodiment, the planarization process can include a chemical mechanical polish (CMP) to form gate electrodes 162.

The wafer 100 now includes logic devices 200 and I/O devices 202 co-integrated in a streamlined process sequence. The logic devices 200 include a single gate (SG) dielectric while the I/O devices 202 include an extended gate (EG) dielectric. The second gate dielectric layer 158 is common to both logic devices 200 and I/O devices 202. The I/O devices 202 include the first gate dielectric layer 150 as well. The first gate dielectric layer 150 can be fine-tuned with regard to its thickness since the first gate dielectric layer 150 is independently applied to the constructed fin 146. The first gate dielectric layer 150 conformally follows faceted portions 148 on a surface of the constructed fin 146, which can be employed to increase the interface area between the gate electrodes and the constructed fin 146.

In accordance with embodiments of the present invention, the wafer 100 includes nanosheet devices (e.g., logic devices 200) and fin devices (e.g., I/O devices) on a same wafer or chip. Device channels of the logic devices 200 include nanosheets, which include the semiconductor layers 124. Device channels of the I/O devices 202 include constructed fins 146.

Referring again to the layout views 102 and 104 of FIG. 1, device channels can be employed to support an epitaxial growth process, which is performed to form source(S) and drain (D) regions as shown in the layout views 102 and 104. Processing continues with the formation of interlevel dielectric layers, middle of the line (MOL) contacts (e.g., gate and S/D contacts), and back end of line (BEOL) processing for metal interconnect structures.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements of features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
an input/output device having a constructed fin channel extending orthogonally relative to a plane of a substrate, the constructed fin channel including faceted portions;
a first gate dielectric layer disposed on the faceted portions;
a logic device having a nanosheet channel; and
a second gate dielectric layer disposed on the first gate dielectric layer on the nanosheet channel.

2. The semiconductor device as recited in claim 1, wherein the faceted portions include periodic faceted surfaces having a periodicity in accordance with nanosheets.

3. The semiconductor device as recited in claim 1, wherein the faceted portions include a diamond-like shape.

4. The semiconductor device as recited in claim 1, wherein the constructed fin channel includes inner spacers embedded therein.

5. The semiconductor device as recited in claim 1, wherein the first gate dielectric layer includes a thickness greater than a gap between nanosheets in the nanosheet channel.

6. The semiconductor device as recited in claim 5, wherein the thickness is greater than 3 nm.

7. The semiconductor device as recited in claim 1, wherein the constructed fin channel includes nanosheets joined by epitaxial semiconductor material.

8. A semiconductor device, comprising:
an input/output device having a constructed fin channel extending orthogonally relative to a plane of a substrate, the constructed fin channel including faceted portions with peaks and valleys on an outer surface of the constructed fin channel;
a first gate dielectric layer disposed on the faceted portions over the peaks and valleys of the outer surface;
a logic device having a nanosheet channel; and
a second gate dielectric layer disposed on the first gate dielectric layer on the nanosheet channel.

9. The semiconductor device as recited in claim 8, wherein the faceted portions include periodic faceted surfaces having a periodicity in accordance with nanosheets.

10. The semiconductor device as recited in claim 8, wherein the faceted portions include a diamond-like shape.

11. The semiconductor device as recited in claim 8, wherein the constructed fin channel includes inner spacers embedded therein.

12. The semiconductor device as recited in claim 8, wherein the first gate dielectric layer includes a thickness greater than a gap between nanosheets in the nanosheet channel.

13. The semiconductor device as recited in claim 12, wherein the thickness is greater than 3 nm.

14. The semiconductor device as recited in claim 8, wherein the constructed fin channel includes nanosheets joined by epitaxial semiconductor material.

15. A semiconductor device, comprising:
an input/output device having a constructed fin channel extending orthogonally relative to a plane of a substrate, the constructed fin channel including faceted portions with peaks and valleys on an outer surface of the constructed fin channel;
a first gate dielectric layer disposed on the faceted portions;
a second gate dielectric layer disposed on the first gate dielectric layer;
a first gate electrode on the second gate dielectric layer, the first gate electrode having a profile that conforms with the peaks and valleys of the outer surface of the constructed fin channel; and
a logic device having a nanosheet channel.

16. The semiconductor device as recited in claim 15, wherein the faceted portions include periodic faceted surfaces having a periodicity in accordance with nanosheets.

17. The semiconductor device as recited in claim 15, wherein the faceted portions include a diamond-like shape.

18. The semiconductor device as recited in claim 15, wherein the constructed fin channel includes inner spacers embedded therein.

19. The semiconductor device as recited in claim 15, wherein the first gate dielectric layer includes a thickness greater than a gap between nanosheets in the nanosheet channel.

20. The semiconductor device as recited in claim 15, wherein the constructed fin channel includes nanosheets joined by epitaxial semiconductor material.
